(19) United States
(12) Patent Application Publication
(10) Pub. No.: US 2011/0005595 A1
(43) Pub. Date: Jan. 13, 2011

(54) SOLAR CELL MODULE AND THE FABRICATION METHOD OF THE SAME

(76) Inventors: Yu-Chih YANG, Hsinchu (TW); Wu-Tsung Lo, Hsinchu (TW)

Correspondence Address: Muncy, Geissler, Olds & Lowe, PLLC, 4000 Legato Road, Suite 310, FAIRFAX, VA, 22033, US

(21) Appl. No.: 12/835,229

(22) Filed: Jul. 13, 2010

(30) Foreign Application Priority Data
Jul. 13, 2009 (TW) 098123682

(51) Int. Cl. H01L 31/0232

(52) U.S. Cl. 136/259

(57) ABSTRACT

The application illustrates a solar cell module, included a base device, a solar cell on the base device, and a concentrator on the solar cell. The concentrator directly contacts with the solar cell and concentrates the light to the solar cell for opto-electric transformation.

### CROSS REFERENCE TO RELATED APPLICATIONS

This application claims the right of priority based on Taiwan Patent Application No. 098123682 entitled “A Solar Cell Module and the Fabrication Method of the Same”, filed Jul. 13, 2009, which is incorporated herein by reference and assigned to the assignee herein.

### TECHNICAL FIELD

The application generally relates to a solar cell module and the fabrication method of the same, and more particularly to a solar cell module with a concentrator combined a primary concentration device with a secondary concentration device and the fabrication method of the same.

### BACKGROUND

Due to the shortage of the petroleum energy, people are much aware of the importance of the environment protection, and thus research and develop aggressively the technology relates to the substitute energy and the recycle energy in recent years. The goal is to reduce the dependence upon the petroleum energy and the influence of such use on the environment. In numerous technologies of the substitute energy and the recycle energy, the solar cell is the most noticeable. Because the solar cell can directly transfer the solar energy to the electrical energy without generating the harmful material such as carbon dioxide or nitrides during process, the pollution to the environment is largely reduced.

The efficiency of electric power generation of the solar cell module structure is currently improved by using the huge lens to focusing the light on a small area. Beside, the solar cell can work well only when it is located nearby the focal point. As FIG. 1 shows, the sun light is concentrated on the solar cell 18 by using the huge lens 2, and it has a focal length D between the huge lens 2 and the solar cell 18 which is about tens centimeters. The solar cell module formed by the above structure is large-sized and expensive.

### SUMMARY

The application provides a concentrator on the solar cell module comprising a primary concentration device and a secondary concentration device, wherein the primary concentration device further comprising a reflective concentration device formed by a plurality of reflective concentration lens.

The application provides a concentrator for the solar cell module comprising a primary concentration device and a secondary concentration device, wherein the secondary concentration device further comprises a light-guiding concentration device, which can be a light-guiding plate.

The application provides a concentrator for the solar cell module comprising a primary concentration device and a secondary concentration device, wherein the secondary concentration device further comprises a light-guiding concentration device, wherein the front side of the light-guiding concentration device is a flat plane, the back side of the light-guiding concentration device has a particular angle or configuration that can direct the light to a certain direction.

The application provides a concentrator on the solar cell module comprising a primary concentration device and a secondary concentration device, wherein the secondary concentration device further comprises a light-guiding concentration device, wherein the back side of the light-guiding concentration device is a flat plane, inclined plane, paraboloid plane, complex plane, or aspherical reflective plane.

The application provides a concentrator on the solar cell module comprising a primary concentration device and a secondary concentration device, wherein the secondary concentration device further comprising a light-guiding concentration device, wherein the front side of the light-guiding concentration device is a flat plane, and the back side of the light-guiding concentration device is a pyramidal or protuberance reflective structure that can direct the light to a certain direction.

The application provides a solar cell module having a base device comprising a back substrate and a heat sink on the back substrate, wherein the back substrate comprises a material having a good thermal conductivity like metal, semiconductor, or ceramic.

The application provides a solar cell module having a base device comprising a back substrate and a heat sink on the back substrate, wherein the heat sink comprises a material having a good thermal conductivity like metal, semiconductor, or ceramic.

The application provides a solar cell module, wherein the solar cell is a concentration-type solar cell.

The application provides a solar cell module, wherein the solar cell is formed by the semiconductor material.

The application provides a solar cell module, wherein the concentrator directly contacts with the solar cell and directs the light to the solar cell for opto-electric transformation.

### BRIEF DESCRIPTION OF THE DRAWINGS

The foregoing aspects and many of the attendant advantages of this application will become more readily appreciated as the same becomes better understood by reference to the following detailed description, when taken in conjunction with the accompanying drawings, wherein:

FIG. 1 illustrates a known solar cell module structure;

FIG. 2 illustrates a sectional view of the solar cell module in accordance with one embodiment of the present application;

FIG. 3 illustrates a sectional view of the reflective concentration device in accordance with one embodiment of the present application;

FIG. 4 illustrates a sectional view of the light-guiding concentration device in accordance with one embodiment of the present application;

FIG. 5 illustrates a sectional view of the base device in accordance with one embodiment of the present application;

FIG. 6 illustrates a sectional view of the solar cell module in accordance with another embodiment of the present application;

FIG. 7 illustrates a sectional view of the solar cell module in accordance with another embodiment of the present application.

### DETAILED DESCRIPTION OF THE PREFERRED EMBODIMENTS

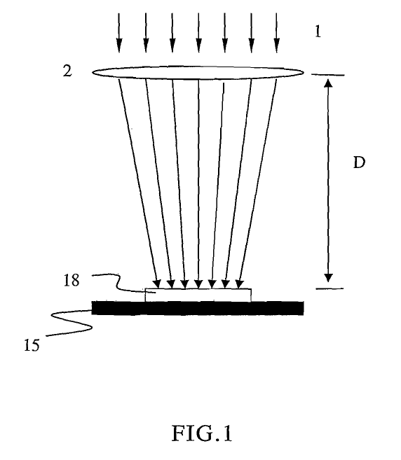

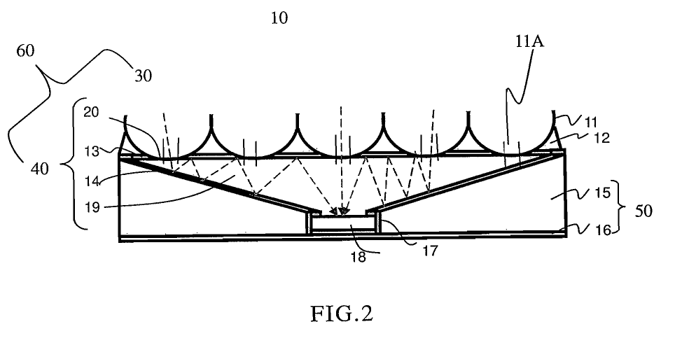

A solar cell module section view structure in accordance with one embodiment of the application shown in FIG. 2, it comprises a base device 50, a solar cell 18, and a concentrator 60, wherein the concentrator comprises a primary concentration device 30 and a secondary concentration device 40. The primary concentration device further comprises a reflective concentration device formed by the plurality of reflective concentration lens. The focal length of the reflective concentration lens is about several centimeters, which is smaller than that of the huge lens 2 shown in FIG. 1, so the volume of the solar cell module with a primary concentration device 30 in accordance with one embodiment of the application is much smaller than that of the conventional solar cell module. The secondary concentration device 40 further comprises a light-guiding concentration device 19, wherein the light-guiding concentration device can be a light-guiding plate. The light is focused by the primary concentration device 30 then injected into the secondary concentration device 40. The light-guiding concentration device 19 of the secondary concentration device 40 can diffuse and propagate the light because of the total reflection that occurs when the index of refraction of the light-guiding material is higher than that of the external medium. The light injected from different angles is reflected by the reflective coating layers 13, 14 on the front side and the back side of the light-guiding concentration device, and is concentrated on and absorbed by the solar cell 18 located at the center for opto-electric transformation by operating with the suitable angle and configuration of the back side of the light-guiding concentration device. The current generated by the opto-electric transformation can be conducted by the circuitry (the figure is not shown) designed between the heat sink 15 and the back substrate 16 of the base device.

The manufacture steps of the above mentioned solar cell module are described in below:

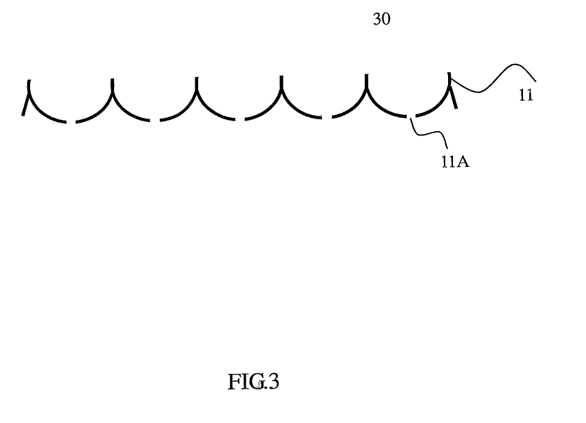

A concentrator 60 is formed by a primary concentration device 30 combined with a secondary concentration device 40. The primary concentration device 30 comprises a reflective concentration device formed by a plurality of reflective concentration lens 11. As FIG. 3 shows, the light-incident surface of the reflective concentration lens can be shaped in circular, square, oval-shaped, or polygon. Opening 11A allows the light being injected into the secondary concentration device 40.

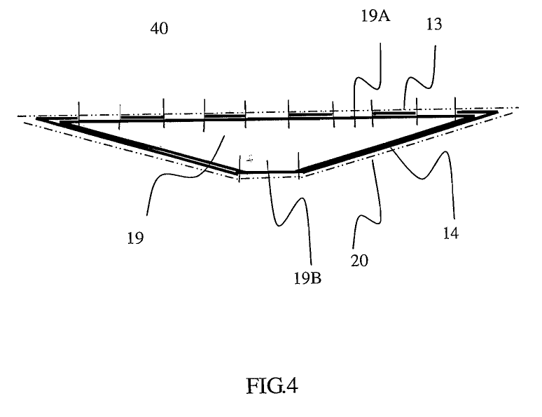

A secondary concentration device 40 is located below the primary concentration device 30 and comprises a light-guiding concentration device 19 to have the light focus on the center region as shown in FIG. 4. The light-guiding concentration device 19 is a device having the front side as a flat plane and the back side with suitable angle and configuration which is made of the light-guiding material by the injection, sawing, polishing, or sculpture technology. The back side of the light-guiding concentration device can be a flat, inclined, parabolic, compound parabolic, or non-spherical reflective plane. By lithography process, the photo resist is defined in the light-incident area 19A on the front side of the secondary concentration device, and in the area 19B located on the back side of the secondary concentration device where the light is focused and propagated to the solar cell, then the front side and the back side of the second concentration device are coated with reflective material such as metal like silver, aluminum metal, or dielectric layer like silicon oxide, titanium oxide, aluminum oxide. Finally, the photo resist is removed, and the front light-incident area 19A and the back side output light area 19B of the secondary concentration device is exposed to complete the reflective coating layers 13, 14 manufacturing process. Further, to facilitate the light collected from the reflective concentration lens 11 to be injected into the secondary concentration device 40 and to be propagated to the solar cell 18 from the secondary concentration device, an anti-reflective coating layer 20 is formed to cover the whole surface of the front reflective coating layer 13 and/or the back reflective coating layer 14 of the secondary concentration device respectively by evaporation or deposition. The secondary concentration device comprises plastic, glass, or organic material.

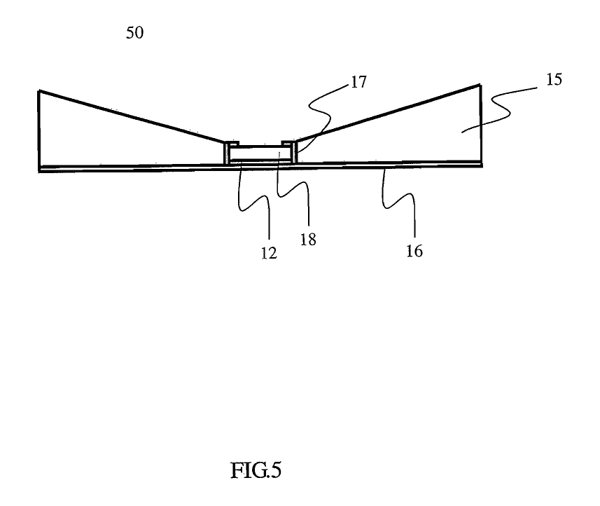

The solar cell 18 can be a concentrative solar cell in this embodiment, which is a multi junction solar cell made of the semiconductor material. The solar cell 18 is connected with the back substrate 16 and the heat sink 15 by the metal connecting layer 12, and a circuitry is formed (the figure is not shown) between the back substrate and the heat sink to conduct the current generated by the solar cell form the bottom thereof. Beside, an isolation layer 17 is formed on two sides of the solar cell 18 by the isolation glue to be isolated from the heat sink 15 as shown in FIG. 5. The back substrate 16 can comprise a material having a good thermal conductivity like metal, semiconductor, or ceramic. The heat sink 15 can comprise a material having a good thermal conductivity like metal, semiconductor, or ceramic.

Then, the opening 11A is aligned and combined with the front light-incident area 19A of the secondary concentration device to form a concentrator 60, and the concentrator is combined with the base device 50 of the solar cell 18, so the concentrator can directly contact with the solar cell to collect the light into the solar cell and proceed the opto-electric transformation. The solar cell module 10 is then accomplished with a small area which can achieve low cost, large area effect, high efficiency without a huge concentration module as FIG. 2 shows.

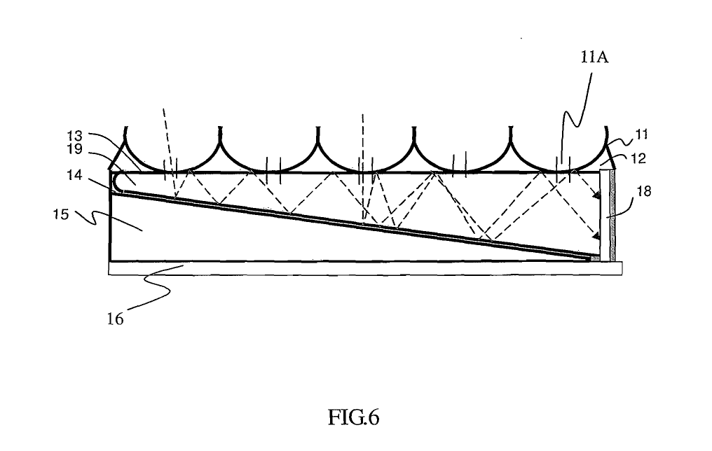

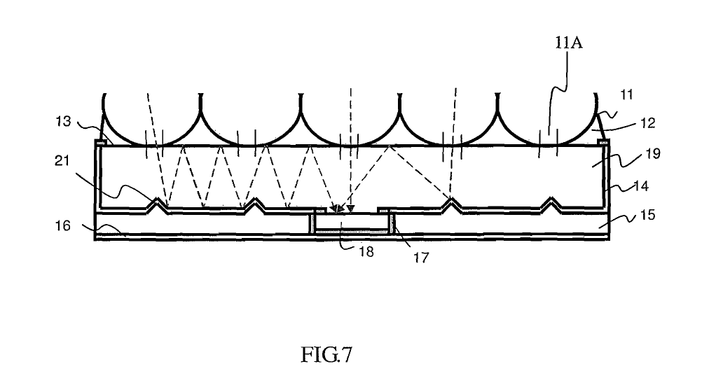

Besides the above embodiments, this application includes another two embodiments disclosing the following various structures. As FIG. 6 shows, the solar cell 18 concentrated the light is disposed on the sidewall of the light-guiding concentration device 19. After the light is concentrated by the primary concentration device, it is injected into the secondary concentration device, and the light injected in different angles is reflected in the secondary concentration device. With the suitable angle and configuration of the back side, the light can be reflected and focused on the solar cell 18 and absorbed for the opto-electric transformation. The current generated by the transformation is conducted by the circuitry designed between the heat sink 15 and the back substrate 16 of the base device 50 (not shown in the figure). Another structure has a flat front side and flat backside for the light-guiding concentration device 19, and has a pyramidal or protuberance reflective structure 21 located on the back side of the light-guiding concentration device below the secondary concentration device corresponding to the opening 11A to reflect the direct incident light with certain angle(s) to be focused on the concentration direction of the solar cell 18. Please refer to FIG. 7.

Other embodiments of the application will be apparent to those having ordinary skill in the art from consideration of the specification and practice of the application disclosed herein. It is intended that the specification and examples be considered as exemplary only, with a true scope and spirit of the application being indicated by the following claims.

We claim:

1. A solar cell module, comprising:
a base device;
a solar cell on the base device; and
a concentrator on the solar cell comprises a primary concentration device and a secondary concentration device, wherein the concentrator directly contacts with the solar cell and concentrates the light to the solar cell for opto-electric transformation.

2. The solar cell module according to claim 1, further comprising:
a back substrate below the solar cell; and
a heat sink on the back substrate and surrounding the solar cell.

3. The solar cell module according to claim 1, wherein the primary concentration device further comprising a reflective concentration device formed by a plurality of reflective concentration lens.

4. The solar cell module according to claim 1, wherein the secondary concentration device further comprising a light-guiding concentration device.

5. The solar cell module according to claim 4, wherein the light-guiding concentration device can be a light-guiding plate.

6. The solar cell module according to claim 4, wherein the front side of the light-guiding concentration device is a flat plane, and the back side of the light-guiding concentration device has a particular angle or configuration that can direct the light to a certain direction.

7. The solar cell module according to claim 2, further comprising an insulating layer between the heat sink and the solar cell.

8. The solar cell module according to claim 2, wherein the back substrate and the heat sink comprising a material having a good thermal conductivity, such as metal, semiconductor, or ceramic.

9. The solar cell module according to claim 2, further comprising a circuitry between the back substrate and the heat sink.

10. The solar cell module according to claim 1, wherein the solar cell is a concentrative solar cell.

11. The solar cell module according to claim 1, wherein the solar cell comprising semiconductor material.

12. The solar cell module according to claim 7, wherein the insulating layer is made of insulating colloid.

13. The solar cell module according to claim 4, wherein the light-guiding concentration device comprising plastic, glass, or organic material.

14. The solar cell module according to claim 4, further comprising a reflective coating layer on the front side of the light-guiding concentration device.

15. The solar cell module according to claim 14, wherein the reflective coating layer comprising silver, aluminum metal, or silicon oxide, titanium oxide, aluminum oxide, or dielectric material.

16. The solar cell module according to claim 4, further comprising a reflective coating layer on the back side of the light-guiding concentration device.

17. The solar cell module according to claim 16, wherein the reflective coating layer comprising silver, aluminum metal, or silicon oxide, titanium oxide, aluminum oxide, and dielectric material.

18. The solar cell module according to claim 4, wherein the back side of the light-guiding concentration device is a flat plane, inclined plane, paraboloid plane, complex plane, or aspherical reflective plane.

19. The solar cell module according to claim 3, wherein the light-incident surface of the plurality of reflective concentration lens is square, circle, oval-shaped, or polygon.

20. The solar cell module according to claim 4, wherein the front side of the light-guiding concentration device is a flat plane, and the back side of the light-guiding concentration device is a pyramidal or protuberance reflective structure to direct the light to a certain direction.
